(19) United States
(12) Patent Application Publication
(10) Pub. No.: US 2011/0272021 A1
(43) Pub. Date: Nov. 10, 2011

(54) METHOD FOR MANUFACTURING SOLAR CELL, AND SOLAR CELL

(75) Inventors: Hirohisa Takahashi, Sammu-shi (JP); Satoru Ishibashi, Sammu-shi (JP); Tatsumi Usami, Sammu-shi (JP); Masanori Shirai, Sammu-shi (JP); Michio Akiyama, Sammu-shi (JP)

(73) Assignee: ULVAC, INC., Chigasaki-shi (JP)

(21) Appl. No.: 13/145,225

(22) PCT Filed: Jan. 21, 2010
(86) PCT No.: PCT/JP2010/000342

§ 371 Date: Jul. 19, 2011

(30) Foreign Application Priority Data
Jan. 23, 2009 (JP) 2009-013584

(51) Int. Cl. H01L 31/0232; H01L 31/18; H01L 31/0224

(52) U.S. Cl. 136/256; 438/71; 257/E31.13

(57) ABSTRACT

A manufacturing method of a solar cell including a transparent conductive film formed on a transparent substrate includes the steps of: preparing a target, the target including ZnO and a material including a substance including an Al or a Ga, the ZnO being a primary component of the target; in a first atmosphere including a process gas, applying a sputter electric voltage to the target and forming a first layer included in the transparent conductive film; in a second atmosphere including a greater amount of an oxygen gas compared to the first atmosphere, applying a sputter electric voltage to the target and forming a second layer on the first layer, the second layer being included in the transparent conductive film; and forming an irregular shape by performing an etching process on the transparent conductive film.

### TECHNICAL FIELD

The present invention relates to a method for manufacturing a solar cell, and a solar cell. In more detail, the present invention relates to a method for manufacturing a solar cell, and a solar cell, which allows minute textures to be formed on a transparent conductive film including a ZnO series material.

The present application claims priority from Japanese Patent Application No. 2009-013584, filed Jan. 23, 2009, the content of which is incorporated herein by reference.

### BACKGROUND ART

Conventionally, solar cells have been used widely. According to solar cells, when an energy particle included in sunlight called a photon hits an i-layer, an electron and a positive hole (hole) are created due to a photovoltaic effect. As a result, the electron moves towards an n-layer, while the positive hole moves towards the p-layer. According to solar cells, light energy is converted to electric energy when an electron, created by a photovoltaic effect, is extracted from an upper electrode and a back surface electrode.

FIG. 15 is a schematic cross sectional diagram of an amorphous silicon solar cell.

According to a solar cell 100, an upper electrode 103, a top cell 105, an intermediate electrode 107, a bottom cell 109, a buffer layer 110, and a back surface electrode 111 are layered in series on top of a surface of a glass substrate 101. The upper electrode 103 includes a zinc oxide series transparent conductive film. The top cell includes an amorphous silicon. The intermediate electrode 107 includes a transparent conductive film, and is provided between the top cell 105 and the bottom cell 109. The bottom cell 109 includes a microcrystal silicon. The buffer layer 110 includes a transparent conductive film. The back surface electrode 111 includes a metal film.

The top cell 105 is a three-layered structure including a p-layer (105p), an i-layer (105i), and an n-layer (105n). Among these, the i-layer (105i) includes amorphous silicon. In addition, similar to the top cell 105, the bottom cell 109 is also a three-layered structure including a p-layer (109p), an i-layer (109i), and an n-layer (109n). Among these, the i-layer (109i) includes microcrystal silicon.

According to such a solar cell 100, the sunlight entering from the glass substrate 101 side is reflected at the back surface electrode 111 after passing through the upper electrode 103, the top cell 105 (p-i-n layer), and the buffer layer 110. Certain configurations are made to the solar cell in order to enhance the effectiveness of making a conversion to light energy. Examples of such configurations include a structure reflecting the sunlight at the back surface electrode 111, a structure called a texture on the upper electrode 101 which achieves a prism effect elongating the light path of the incident sunlight, and achieves an effect to confine light. The texture is provided on the upper electrode 101. The buffer layer 110 is provided to prevent the dispersion of the metal film used in the back surface electrode 111.

According to solar cells, the wavelength band at which a photovoltaic effect is obtained differs depending on the type of device structures used in the solar cell. However, regarding any solar cell, it is necessary that the transparent conductive film, included in the upper electrode, have a characteristic such that light, which is absorbed at the i-layer, is passed through. It is also necessary that the transparent conductive film have electrical conductivity so as to extract the electron created by the photovoltaic power. As a result, according to solar cells, an FTO, which is obtained by adding fluorine to SnO₂ as an impurity, as well as a ZnO series oxide semiconductor thin film are used. Similarly, it is necessary that the buffer layer have a characteristic of letting light pass through, which reflects at the back surface electrode in order to be absorbed by the i-layer. It is also necessary that the buffer layer have a characteristic such that light, which was reflected by the back surface electrode, is passed through. Furthermore, it is necessary that the buffer layer have electrical conductivity so as to transport the positive hole to the back surface electrode.

Generally speaking, the three elements that a transparent conductive film used in a solar cell is required to have as characteristics are electrical conductivity, optical properties, and a textured structure. First, concerning the first characteristic, electrical conductivity, a low electrical resistance is required to extract electricity which was generated. Generally speaking, the FTO, used as a transparent conductive film for solar cells, is a transparent conductive film created by the CVD. Electrical conductivity is obtained by replacing O with F, by adding F to the SnO₂. Further, a ZnO series material, which is widely regarded as a post-ITO, may be used to create a film by sputtering. According to such a ZnO series material, electrical conductivity is obtained by adding to ZnO, a material including Al and Ga as well as oxygen deficiency.

Second, since a transparent conductive film for solar cells is primarily used at an incident light position (surface), an optical property is required such that a wavelength band, absorbed by the electricity generating layer, is passed through.

Third, a textured structure is necessary to scatter light so that sunlight is effectively absorbed by the electricity generating layer. Normally, ZnO series thin films created by a sputtering process have a flat surface. Therefore, in order to form a textured structure having an irregular surface, a texture forming process such as wet etching and the like is necessary.

However, when a sputtering method is used to form a film including a ZnO series material, and thereafter, a TCO used for solar cells is formed by wet etching, a ZnO series material possesses a prominent C axis orientation. As a result, it is difficult to form a minute texture.

### PRIOR ART DOCUMENT

### Patent Document

[Patent Document 1] Japanese Unexamined Patent Application, First Publication No. S58-57756
[Patent Document 2] Published Japanese Translation No. H02-503615 of PCT International Publication

### DISCLOSURE OF INVENTION

### Problems to be Solved by the Invention

The present invention is made according to the problems described above. Thus, the present invention provides a method for manufacturing a solar cell which allows a minute texture to be formed even when a transparent conductive film including a ZnO series material is formed using a sputtering method. The present invention also provides a method for manufacturing a solar cell which allows a solar cell possessing a high degree of photoelectric conversion efficiency to be manufactured. In addition, the present invention provides a solar cell including a minute texture on a transparent conductive film including a ZnO series material. The present invention also provides a solar cell possessing a high photoelectric conversion efficiency.

### Means for Solving the Problems

In order to solve the problems described above, the following configurations are made.

A manufacturing method of a solar cell according to a first aspect of the present invention including a transparent conductive film formed on a transparent substrate includes the steps of: preparing a target, the target including ZnO and a material including a substance including an Al or a Ga, the ZnO being a primary component of the target; in a first atmosphere including a process gas, applying a sputter electric voltage to the target and forming a first layer included in the transparent conductive film (step A); in a second atmosphere including a greater amount of an oxygen gas compared to the first atmosphere, applying a sputter electric voltage to the target and forming a second layer on the first layer, the second layer being included in the transparent conductive film; and forming an irregular shape by performing an etching process on the transparent conductive film (step B).

A solar cell according to a second aspect of the present invention includes a transparent substrate; a transparent conductive film including a first layer and a second layer, the transparent film also including ZnO as a primary component, the transparent film also including an irregular shape, the first layer being placed at a position close to the transparent substrate, the second layer being placed at a position close to an electricity generating layer, the second layer including a greater amount of oxygen compared to an amount of oxygen included in the first layer; an electricity generating layer formed on the transparent conductive film; and a back surface electrode formed on the electricity generating layer.

According to a solar cell based on the second aspect of the present invention, it is preferred that the amount of oxygen included in the second layer be greater than the amount of oxygen included in the first layer by 0.5-3 mass %.

According to a solar cell based on the second aspect of the present invention, it is preferred that the second layer is placed on the first layer so that the second layer is in contact with the first layer. Further, it is preferred that the irregular form have a depth which is greater than a thickness of the second layer. It is also preferred that the irregular form be formed on the second layer.

### EFFECTS OF THE INVENTION

According to a manufacturing method of a solar cell based on the present invention, when a ZnO series material is formed on a transparent substrate using a sputtering method in a process forming the transparent substrate, step A and step B are performed in this order. In step A, a first layer possessing conductivity is formed. In step B, a second layer is formed on the first layer. The second layer includes a texture on the first layer. In addition, the amount of oxygen gas in a first atmosphere in which the step A is performed is greater than the amount of oxygen gas in a second atmosphere in which the step B is performed. The orientation of a film making up the second layer formed according to this method is disturbed. As a result, it is possible to form a minute texture.

Consequently, according to the present invention, a prism effect due to a textured structure and an effect to confine light may be adequately obtained. Thus, it is possible to manufacture a solar cell possessing a high degree of photoelectric conversion efficiency.

Further, a solar cell according to the present invention includes a transparent substrate, a transparent conductive film, a conductive film, and a back surface electrode. The transparent conductive film includes a first layer and a second layer. The first layer is positioned near the transparent substrate. The second layer includes more oxygen compared to the amount of oxygen included in the first layer. The second layer is positioned near the conductive layer. The transparent conductive layer includes ZnO as a primary component, and is formed on the transparent substrate.

According to this configuration, a minute texture may be formed because the orientation of the films forming the second layer is disturbed. Therefore, it is possible to obtain a solar cell including a textured structure.

According to this textured structure, a prism effect and an effect of confining light may be obtained. As a result, it is possible to obtain a solar cell possessing a high degree of photoelectric conversion efficiency.

### BRIEF DESCRIPTION OF THE DRAWINGS

FIG. 1 is a cross sectional view showing a solar cell formed by a manufacturing method according to the present invention.

FIG. 2 is a schematic structural diagram of a film forming device, seen from above, showing a film forming device used in a manufacturing method according to the present invention.

FIG. 3 is a schematic structural diagram of a film forming device, seen from above, showing a film forming chamber of a film forming device used in a manufacturing method according to the present invention.

FIG. 4 is a schematic structural diagram of a film forming device, seen from above, showing a film forming chamber of a film forming device used in a manufacturing method according to the present invention.

FIG. 5 is a diagram showing a relationship between a film forming speed and pressure.

FIG. 6 is a schematic diagram showing an example of a consecutive film forming device.

FIG. 7 is a schematic diagram showing an example of a consecutive film forming device.

FIG. 8A is a schematic diagram showing an example of a consecutive film forming device.

FIG. 8B is a schematic diagram showing a structure of a film forming device.

FIG. 8C is a schematic diagram showing a structure of a film forming device.

FIG. 9 is a diagram showing an SEM image of a transparent conductive film obtained in Working Example 1.

FIG. 10 is a diagram showing an SEM image of a transparent conductive film obtained in Working Example 2.

FIG. 11 is a diagram showing an SEM image of a transparent conductive film obtained in Working Example 3.

FIG. 12 is a diagram showing an SEM image of a transparent conductive film obtained in Comparative Example 1.

FIG. 13 is a diagram showing a measuring result obtained by measuring a transparent conductive film obtained in a Working Example using an XRD measurement.

FIG. 14 is a diagram showing a measuring result obtained by measuring a transparent conductive film obtained in a Comparative Example using an XRD measurement.

FIG. 15 is a cross sectional diagram showing a conventional solar cell.

### EMBODIMENTS FOR CARRYING OUT THE INVENTION

Hereinafter, a manufacturing method for a solar cell and a solar cell according to an embodiment of the present invention is described with reference to the diagrams.

In addition, in each of the diagrams used in the following description, the dimensions and ratios of each component are differed from the actual dimensions and ratios so that each component may be large enough to be recognized in the diagram.

Incidentally, the following description does not limit the technical scope of the present invention in any way. Various alterations may be made within the gist of the present invention.

### (Solar Cell)

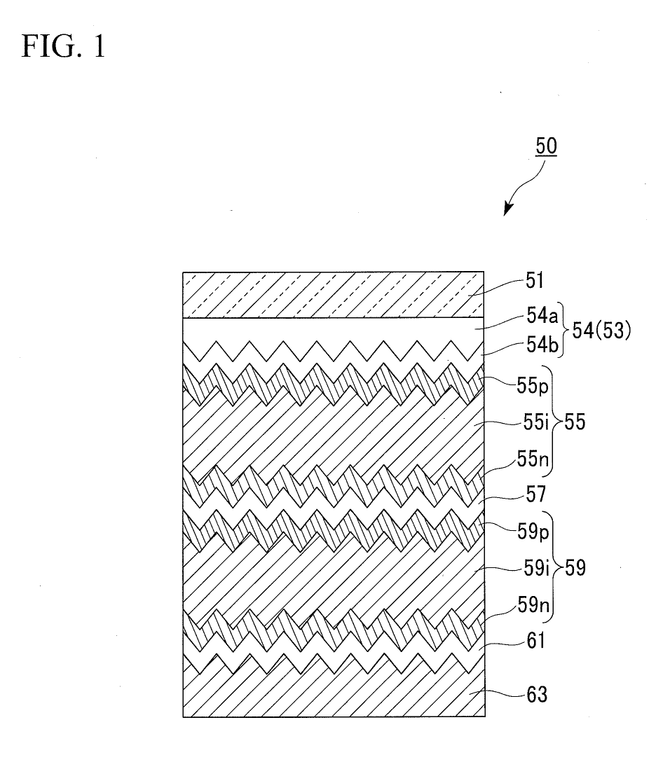

First, a solar cell according to the present embodiment is described based on FIG. 1.

FIG. 1 is a cross sectional diagram showing a configuration of a solar cell. According to the solar cell 50, an upper electrode 53, a top cell 55, an intermediate electrode 57, a bottom cell 59, a buffer layer 61, and a back surface electrode 63 are layered on a surface of a glass substrate 51 (transparent substrate) in series. The upper electrode 53 includes a transparent conductive film 54 of an oxidized zinc series. The top cell 55 includes an amorphous silicon. The intermediate electrode 57 includes the transparent conductive film 54. The intermediate electrode 57 is provided between the top cell 55 and the bottom cell 59. The bottom cell 59 includes a microcrystal silicon. The buffer layer 61 includes a transparent conductive film 54. The back surface electrode 63 includes a metal film.

According to the solar cell 50 based on the present invention, the upper electrode 53 is an electrode into which light enters. The upper electrode 53 is a transparent conductive film 54 including ZnO as a primary component. The transparent conductive film 54 is configured to include a layered structure in which a first layer 54a and a second layer 54b are layered in series. The second layer 54b has a haze ratio which is different from the haze ratio of the first layer 54a. This transparent conductive film 54 is formed using a manufacturing method described below. The transparent conductive film 54 has minute textures. As a result, the solar cell 50 based on the present invention adequately exhibits a prism effect and an effect of confining light due to the textured structure. Thus, the solar cell 50 based on the present invention has a high photoelectron conversion efficiency.

Furthermore, the amount of oxygen contained in the second layer 54b is greater than the amount of oxygen contained in the first layer 54a by 0.5-3 mass %. The amount of oxygen in the second layer 54b is controlled by the manufacturing method described below.

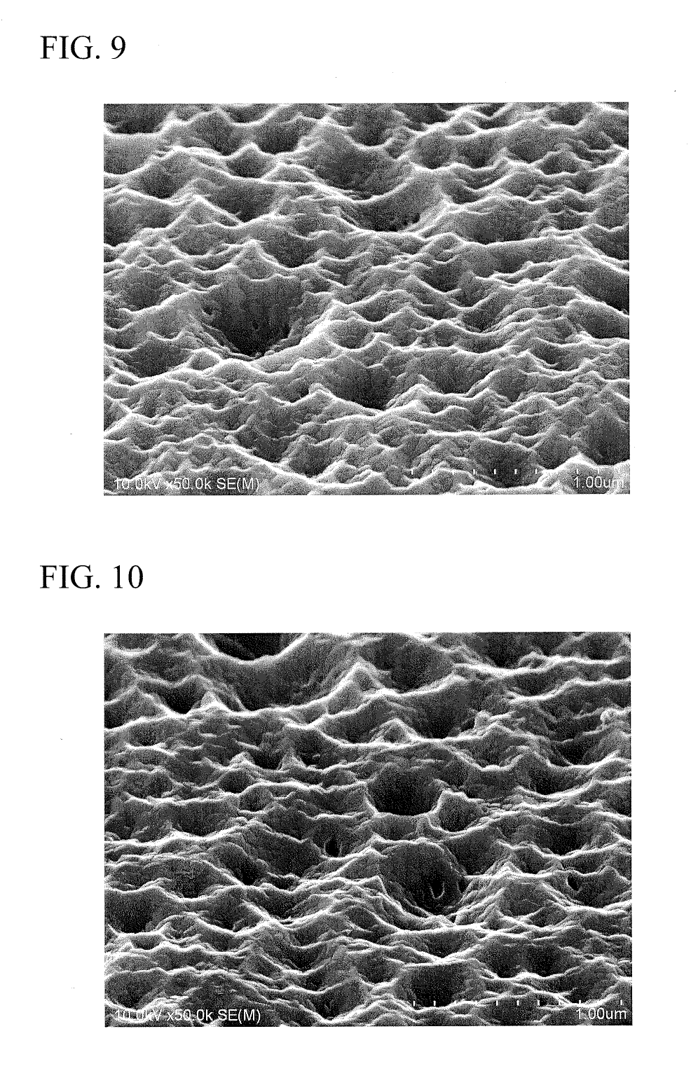

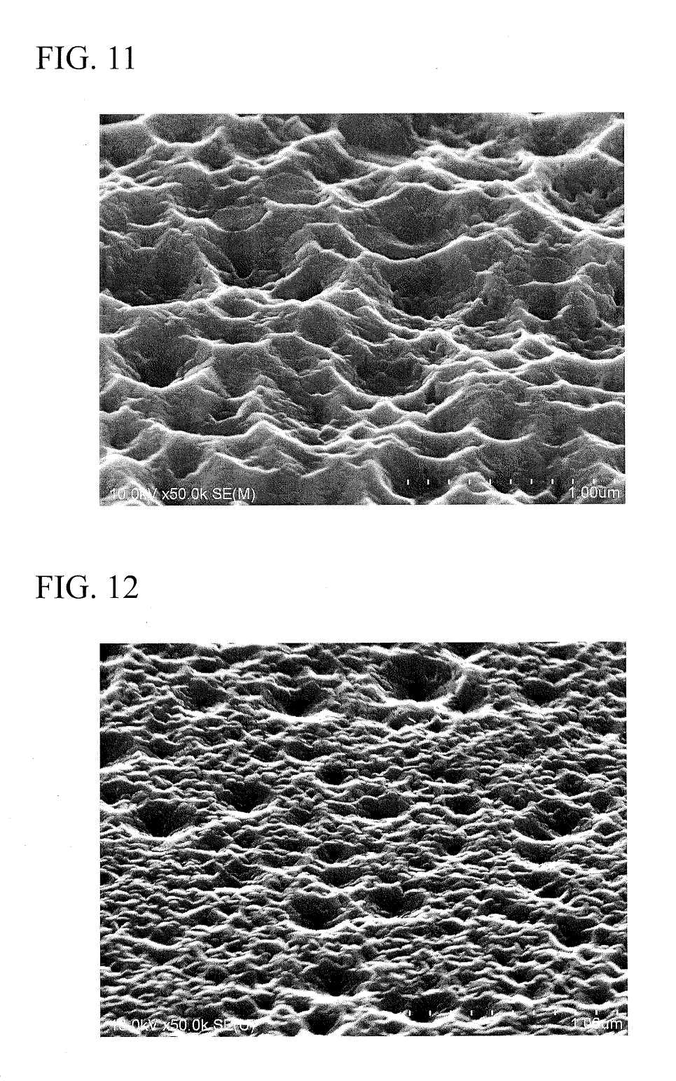

In addition, when an etching is performed on the second layer 54b, which has a greater amount of oxygen compared to the first layer 54a, an irregular shape is formed on a surface of the transparent conductive film 54 including the second layer 54b (see FIGS. 9-11). As a result, the depth of the irregular shape formed on the transparent conductive film 54 is larger than the thickness of the second layer 54b. In addition, this irregular shape is formed on the second layer 54b.

In addition, the solar cell 50 is a tandem type solar cell including an a-Si and a microcrystal Si. According to such a tandem type solar cell 50, a short wavelength light is absorbed by the top cell 55, while a long wavelength light is absorbed by the bottom cell 59.

Thus, it is possible to enhance the efficiency of generating electricity. Incidentally, the film thickness of the upper electrode 53 is 2000 [Å] to 10000 [Å].

The top cell 55 is a three-layered structure including a p-layer 55p (first p layer), an i-layer 55i (first i-layer), and an n-layer 55n (first n-layer). Among these, the i-layer 55i includes an amorphous silicon.

Further, similar to the top cell 55, the bottom cell 59 is a three-layered structure including a p-layer 59p (second p-layer), an i-layer 59i (second i-layer), and an n-layer 59n (second n-layer). Among these, the i-layer (59i) includes a microcrystal silicon.

According to the solar cell 50 structured in this way, when an energy particle included in sunlight called a photon hits an i-layer, an electron and a positive hole (hole) are created due to a photovoltaic effect. As a result, the electron moves towards an n-layer, while the positive hole moves towards the p-layer.

Light energy may be converted into electric energy by extracting the electron, which was created by this photovoltaic effect, from the upper electrode 53 and the back surface electrode 63.

Further, by providing an intermediate electrode 57 between the top cell 55 and the bottom cell 59, a part of light, which passes through the top cell 55 and reaches the bottom cell 59, reflects at the intermediate electrode 57 and reenters from a top cell 55 side. As a result, the sensitivity characteristic of the cell increases, and the effectiveness of generating electricity is enhanced.

Furthermore, sunlight which enters the solar cell 50 via a glass substrate 51 passes through each layer and is reflected at the back surface electrode 63. A textured structure is employed on the solar cell 50 in order to enhance the effectiveness of making a conversion to light energy by achieving a prism effect, which elongates the light path of the incident sunlight, and by achieving an effect to confine light.

As described layer, during a procedure for forming a transparent conductive film 54 included in an upper electrode 53, step A and step B are performed while using a sputtering method to form a transparent conductive film 54 including a ZnO series material. In step A, a first layer 54a having conductivity is created. In step B, a second layer 54b is formed on the first layer 54a. The second layer 54b includes a texture. In addition, the second layer 54b is formed in a second atmosphere having a greater amount of oxygen compared to the amount of oxygen included in a first atmosphere in which the first layer 54a is formed. In this way, after the second layer 54b is formed in an atmosphere having a greater amount of oxygen, an etching method (such as a wet etching method) is performed to create an irregular shape on a surface of the transparent conductive film 54 including the second layer 54b. As a result, it is possible to form a minute texture. Consequently, according to the solar cell 50 manufactured in this way, a prism effect due to a textured structure and an effect to confine light may be adequately obtained. Thus, it is possible to achieve a high degree of photoelectric conversion efficiency.

### (Method for Manufacturing a Solar Cell)

Next, a method for manufacturing a solar cell is described.

According to a manufacturing method of a solar cell based on an embodiment of the present invention, a sputtering method is used. The sputtering method uses ZnO, which is a primary component, and a target, which includes an ingredient including a substance containing Al or Ga. Thus, an upper electrode 53 is formed. The upper electrode 53 includes a transparent conductive film 54. The transparent conductive film 54 includes ZnO as a primary component. When the sputtering method is performed, a sputtering voltage is applied to a target in an atmosphere including a process gas. The target includes the ingredient described above. Then, a sputtering is performed by generating a horizontal magnetic field on a surface of the target. According to this method, a transparent conductive film 54 is formed on a transparent substrate (glass substrate 51). Thus, an upper electrode 53 including a transparent conductive film 54 is formed.

According to a manufacturing method of a solar cell based on the present embodiment, the material used to form the transparent conductive film 54 includes ZnO and a substance containing Al or Ga. A step for forming the upper electrode 53 contains at least step A and step B in this order. In step A, a first layer 54a included in the transparent conductive film 54 is formed. In step B, a second layer 54b included in the transparent conductive film 54 is formed on the first layer 54a. In addition, the second layer 54b is formed in a second atmosphere having a greater amount of oxygen compared to the amount of oxygen included in a first atmosphere in which the first layer 54a is formed.

Therefore, the amount of oxygen in the second atmosphere, in which the second layer 54b including a texture is formed, is greater than the amount of oxygen in the first atmosphere, in which the first layer 54a having conductivity is formed. An etching is performed in the transparent conductive film 54 including the first layer 54a and the second layer 54b formed in this way. As a result, the surface of the second layer 54b undergoes etching. Thus, an irregular shape is formed. As a result, the orientation of a film making up the second layer formed according to this method is disturbed. Therefore, it is possible to form a minute texture.

Consequently, according to the manufacturing method based on the present embodiment, a prism effect due to a textured structure and an effect to confine light may be adequately obtained. Thus, it is possible to manufacture a solar cell possessing a high degree of photoelectric conversion efficiency.

First, according to a manufacturing method of a solar cell based on the present invention, a sputtering device (film forming device) is described. The sputtering device is used when a zinc oxide series transparent conductive film 54 included in the upper electrode 53 is formed.

### (First Sputtering Device)

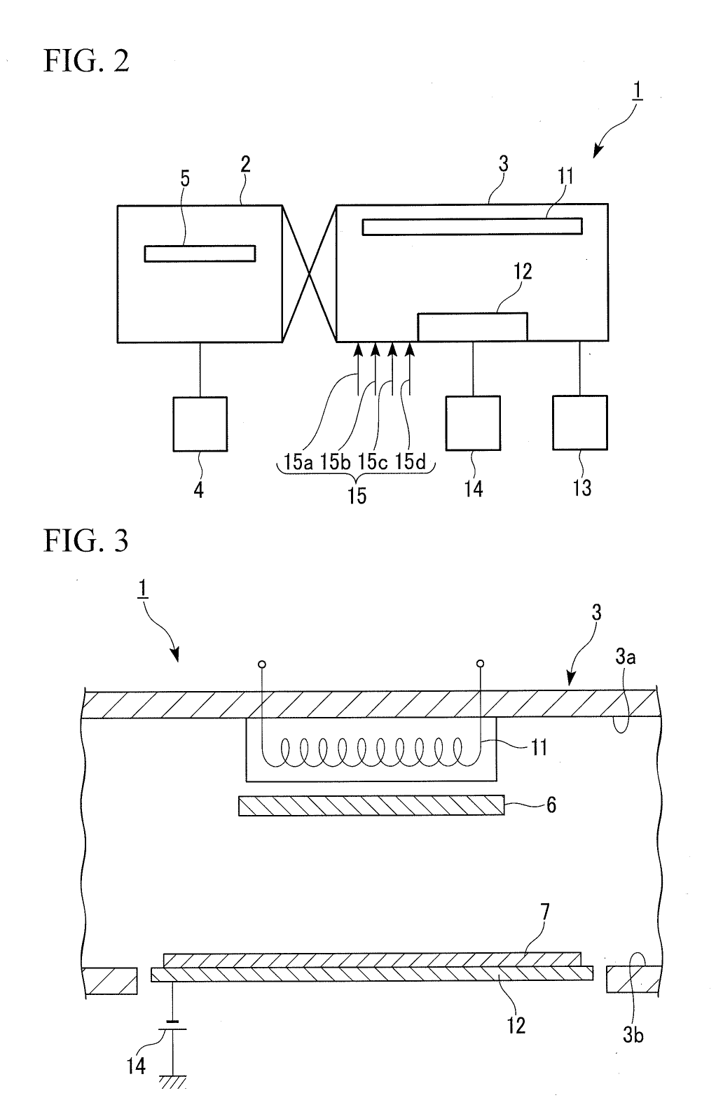

FIG. 2 is a schematic structural diagram of a sputtering device, seen from above, showing a first sputtering device (film forming device) used in a manufacturing method of a solar cell according to the present invention.

FIG. 3 shows a film forming chamber of the sputtering device shown in FIG. 2. FIG. 3 is a cross sectional diagram of the film forming chamber, seen from above.

The sputtering device 1 is an interback type sputtering device. The sputtering device 1 includes a transfer chamber 2 (loading/ejecting chamber) to load/eject a substrate such as an alkali-free glass substrate (not diagrammed), and a film forming chamber 3 (vacuum container) which forms a zinc oxide series transparent conductive film 54 on a substrate.

The transfer chamber 2 is provided with a first exhaust unit 4 which reduces pressure coarsely such as a rotary pump. The exhaust unit 4 reduces the pressure inside the transfer chamber 2. A substrate tray 5 is movably placed inside the transfer chamber 2, in order to retain/transport the substrate.

Meanwhile, a heater 11 is provided to first side surface 3a of the film forming chamber 3 in a longitudinal form to heat the substrate 6 (glass substrate 51). A sputter cathode mechanism 12 (target retaining unit) is provided on a second side surface 3b of the film forming chamber 3 in a longitudinal form to hold the target 7 and apply a predetermined sputter voltage. Further, a high vacuum exhaust unit 13 such as a turbo molecule pump, a power source 14, which applies sputter voltage to the target 7, and a gas introduction unit 15, which introduces gas inside the film forming chamber 3, are provided in the film forming chamber. The high vacuum exhaust unit 13 reduces the pressure inside the film forming chamber 3 to a high vacuum.

The sputtering cathode mechanism 12 includes a metal plate, which is a planar form. This sputtering cathode mechanism 12 fixes the target 7 with a wax material and the like by bonding (fixing). The power source 14 applies a sputtering voltage to the target 7. The sputtering voltage is obtained by superimposing a high-frequency voltage to the direct current voltage. This power source 14 includes a direct current power source and a high-frequency voltage power source (not diagrammed).

The gas introduction unit 15 includes a sputtering gas introduction unit 15a, which introduces sputtering gas such as Ar and the like, a hydrogen gas introduction unit 15b, which introduces hydrogen gas, an oxygen gas introduction unit 15c, which introduces oxygen gas, and a vapor introduction unit 15d, which introduces vapor.

According to this gas introduction unit 15, a hydrogen gas introduction unit 15b, an oxygen gas introduction unit 15c, and a vapor introduction unit 15d are selected according to need, and are used. For example, the gas introduction unit 15 may include two gas introduction units including the hydrogen gas introduction unit 15b and the oxygen gas introduction unit 15c. Further, the gas introduction unit 15 may include two gas introduction units including the hydrogen gas introduction unit 15b and the vapor introduction unit 15d.

### (Second Sputtering Device)

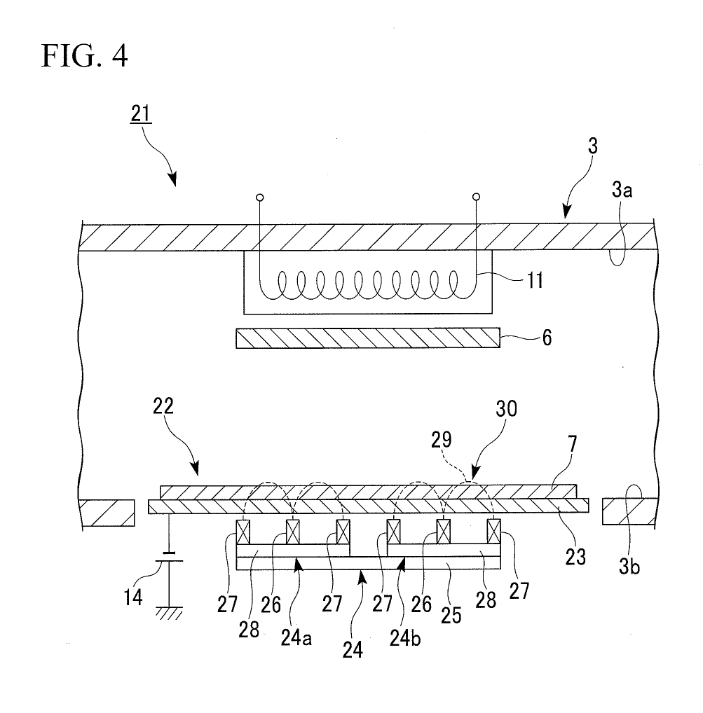

FIG. 4 shows a second sputtering device used in a manufacturing method for manufacturing a solar cell according to the present invention. In other words, FIG. 4 shows a film forming chamber of an interback type magnetron sputtering device. FIG. 4 is a cross sectional view seen from above the film forming chamber.

The magnetron sputtering device 21 shown in FIG. 4 is different from the sputtering device 1 described above in that, a target 7 including a zinc oxide series material is held at a first side surface 3a of the film forming chamber 3. The magnetron sputtering device 21 shown in FIG. 4 is also different from the sputtering device 1 described above in that, a sputter cathode mechanism 22 (target holding unit) is placed in a longitudinal manner. The sputter cathode mechanism 22 generates a predetermined amount of magnetic field.

The sputtering cathode mechanism 22 includes a back surface plate 23, which is bonded (fixed) to the target 7 with a wax material and the like; and also includes a magnetic circuit 24, which is placed along a back surface of the back surface plate 23.

This magnetic circuit 24 generates a horizontal magnetic field on a front surface of the target 7. According to the magnetic circuit 24, a plurality of magnetic circuit units (in FIG. 4, two units are shown) 24a, 24b are integrated by being linked together with a bracket 25. Each of the magnetic circuit units 24a, 24b includes a yoke 28 attached with a first magnet 26 and a second magnet 27. Further, according to a front surface of the first magnet 26 and the second magnet 27 facing the back surface plate 23, a polarity of the first magnet 26 is different from a polarity of the second magnet 27. In other words, at a back surface plate 23 side, the polarity of the first magnet 26 is different from the polarity of the second magnet 27.

According to this magnetic circuit 24, since the first magnet 26 and the second magnet 27 are provided, a magnetic field, represented by the magnetic field lines 29, is generated. As a result, at a front surface of the target 7 between the first magnet 26 and the second magnet 27, a position 30 is generated at which a perpendicular magnetic field equals zero (i.e, a horizontal magnetic field is maximized). It is possible to increase the velocity with which the film is formed by the generation of a high-density plasma at this position 30.

According to the film forming device shown in FIG. 4, a sputtering cathode mechanism 22 is provided in a longitudinal form which generates a desired magnetic field at first side surface 3a of the film forming chamber 3. As a result of this configuration, by setting the sputtering voltage to less than or equal to 340 V, and by setting the maximum value of the strength of the horizontal magnetic field at the front surface of the target 7 to be greater than or equal to 600 Gauss, it is possible to form a transparent conductive film 54 of an oxidized zinc series, or oxidized tin series having a neatly formed crystal lattice.

This transparent conductive film 54 of an oxidized zinc series is resistant to oxidization even if an annealing treatment is conducted at a high temperature after the film is formed. Thus, it is possible to prevent an increase in specific resistance. By applying an oxidized zinc series transparent conductive film 54, formed in this way, as an upper electrode of a solar cell, it is possible to obtain a solar cell having superior heat resistance.

Next, as an example of a manufacturing method for a solar cell according to the present invention, the sputtering device 1 shown in FIGS. 2, 3 is referred to in order to describe a method of forming on top of a transparent substrate, a transparent conductive film 54 of an oxidized zinc series, making up an upper electrode of a solar cell.

First the target 7 is fixed to the sputter cathode mechanism 12 by performing a bonding via a wax material and the like. A zinc oxide type material is used as the target. Examples include an aluminum-added oxidized zinc (AZO) obtained by adding aluminum (Al) by 0.1 to 10 mass %, as well as a gallium-added oxidized zinc (GZO) obtained by adding gallium (Ga) by 0.1 to 10 mass %, and the like. In particular, using an aluminum-added oxidized zinc (AZO) is preferable because a thin film having a low specific resistance may be formed.

Next, for example, a substrate 6 of a solar cell (glass substrate 51) is placed on a substrate tray 5 in a transfer chamber 2. The substrate 6 includes glass. While the substrate tray 5 is placed inside the transfer chamber 2, the pressure inside the transfer chamber 2 and the film forming chamber 3 is roughly reduced by using a coarse exhaust unit 4. As a result, the transfer chamber 2 and the film forming chamber 3 reach a predetermined degree of vacuum, for example 0.27 [Pa] (2.0 [mTorr]). Then, the substrate 6 is transported to the film forming chamber 3 from the transfer chamber 2. This substrate 6 is placed in front of the heater 11 in a condition in which electric power is not provided. At the same time, the substrate 6 is made to face the target 7. Then, this substrate 6 is heated with the heater 11 so that its temperature is controlled to be within the range of 100° C. to 600° C.

Next, the pressure inside the film forming chamber 3 is reduced by undergoing a high vacuuming using the high vacuum exhaust unit 13. After the film forming chamber 3 reaches a predetermined degree of vacuum, for example 2.7×10⁻⁴ [Pa] (2.0×10⁻³ mTorr), a sputtering gas such as Ar and the like is introduced into the film forming chamber 3 by the sputtering gas introduction unit 15. Thus, the interior of the film forming chamber 3 is set to a predetermined pressure (sputtering pressure).

Next, the power source 14 applies a sputtering voltage to the target 7. For example, the sputtering voltage is obtained by superimposing a high-frequency voltage to the direct current voltage. Due to the application of the sputtering voltage, a plasma is generated on the substrate 6. Ion of the sputtering gas such as Ar and the like, which was energized by this plasma collides with the target 7. From this target 7, an element which is included in a material of an oxidized zinc series such as an aluminum-added oxidized zinc (AZO) or a gallium-added oxidized zinc (GZO) and the like is dispersed from this target 7. Thus, a transparent conductive film 54 including an ingredient of an oxidized zinc series is formed on the substrate 6.

According to the present embodiment, the second layer 54b is formed in a second atmosphere having a greater amount of oxygen compared to the amount of oxygen included in a first atmosphere in which the first layer 54a is formed. In other words, a sputtering method is applied to form a first layer 54a in a low oxygen gas atmosphere. The first layer 54a is conductive. Thereafter, a sputtering method is used to form a second layer 54b in a high oxygen gas atmosphere. The second layer 54b includes a texture.

By using the sputtering method to form the second layer 54b in a high oxygen gas atmosphere, the orientation of the film, included in the second layer formed by this method, is disturbed. Therefore, a minute texture may be formed by using a wet etching method (non-isotropic etching method). The wet etching method is a step performed after a sputtering step.

Here a relation between a film forming pressure and a film forming speed at the time of sputtering is described.

The film forming pressure at the time of sputtering depends on the target material or the type of process gas. However, when a magnetron sputtering method is used to form a film, a pressure range of 2 mTorr to 10 mTorr is selected in general. Thus, a film is formed. When the film forming pressure is low, the impedance of the plasma is high. Thus, a discharge may not be made. Even if a discharge is made, the plasma may become unstable.

In contrast, when the film forming pressure is high, the process gas and the sputtered target material undergoes a scattering. Due to this scattering, the efficiency (film forming speed) with which film attaches to the substrate may be reduced. In addition, a film of a sputtered target material may attach to a component placed around the cathode. Thus, an electric short may occur in the cathode and an earth. As a result, the productivity is reduced.

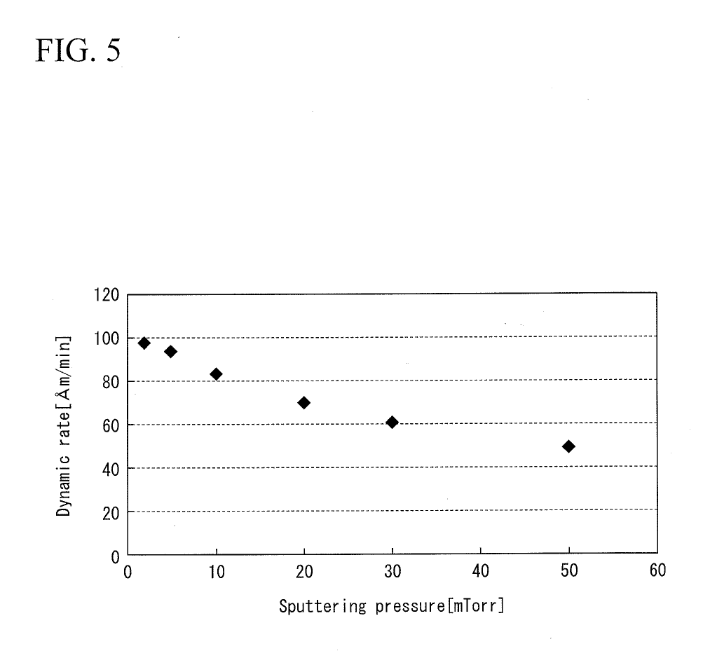

As an example of a case in which the productivity has been reduced, a relation between a film forming speed and pressure is shown in FIG. 5. According to the experimentation shown in FIG. 5, a target is prepared. The target is formed to be a size of 5 inches×16 inches. A primary component of the target is ZnO. Al₂O₃ is included in the target by a mass percentage of 2 mass %. The target undergoes a sputtering at an electric power of 1 kW. As shown in FIG. 5, when the film forming pressure is 5 mTorr, the film forming speed is approximately 93 Å/min. When the film forming pressure is 30 mTorr, the film forming speed is approximately 60 Å/min. In other words, when the film forming pressure changes from 5 mTorr to 30 mTorr, the film forming speed decreases by 30% to 40%.

Next, a description is provided regarding the difference in the concentration of oxygen gas provided at the time of sputtering. A description is also provided regarding the oxygen included in a film.

In order to examine the difference between a film added with oxygen and a film not added with oxygen, an analysis was performed using EPMA (Electron Probe Micro-Analysis). Here, an element of a ZnO thin film of 1000 nm, created on an Si substrate under a condition in which 0 sccm of oxygen is provided, is used. At the same time, an element of a ZnO thin film of 1000 nm, created on an Si substrate under a condition in which 20 sccm of oxygen is provided, is used.

From an analysis using EPMA, it was determined that the amount of oxygen contained in the ZnO thin film, formed under a condition with a large amount of oxygen provision, was greater than the amount of oxygen contained in the ZnO thin film formed under a condition with no amount of oxygen provision.

This result was examined along with a measurement result obtained by using XRD (X-ray Diffraction, X-ray Diffraction Measurement) as shown in FIG. 14. As a result, the orientation of a (004) surface is thought to enhance as oxidization progresses. Thus, the etching process progresses in a plurality of directions. Therefore, it is believed that a minute texture may be formed.

As described above, a transparent conductive film 54, including an oxidized zinc type material, is formed on a substrate 6. Then, this substrate 6 (glass substrate 51) is moved from the film forming chamber 3 to the transfer chamber 2. The pressure inside the transfer chamber 2 is returned to atmospheric pressure. The substrate 6 (glass substrate 51), on which a zinc oxide type transparent conductive film 54 is formed, is removed from the transfer chamber 2. Next, a wet etching process is conducted on the transparent conductive film 54. As a result, a minute texture is formed on a front surface of the transparent conductive film 54. At this time, the orientation of the film of the second layer 54b is disturbed. This is because the second layer 54b, placed on a front surface of the transparent conductive film 54, is formed in a high oxygen gas atmosphere by using a sputtering method. When a wet etching is performed on the second layer 54b including a front surface having a disturbed orientation in this way, an etching process on the second layer 54b progresses in a plurality of directions. Therefore, it is possible to form a minute texture.

As described above, a substrate 6 (glass substrate 51), on which a zinc oxide type transparent conductive film 54 is formed, is obtained. This transparent conductive film 54 has a minute textured structure on its front surface. By applying such a textured structure to a solar cell, it is possible to achieve, to a maximum extent, a prism effect elongating the light path of the incident sunlight and an effect to confine light. As a result, it is possible to obtain a solar cell possessing a high degree of photoelectric conversion efficiency.

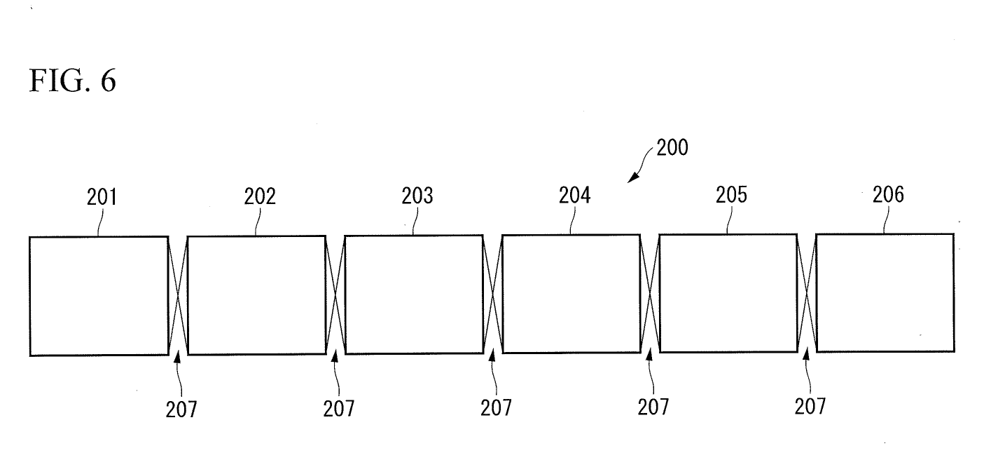

Incidentally, according to the present embodiment, when an inline type film forming device is used to form the first layer 54a and the second layer 54b in series, it is possible to use an inline buffer chamber type film forming device 200 as shown in FIG. 6. This inline buffer chamber type film forming device 200 includes a buffer chamber.

The film forming device 200 includes a load lock chamber 201, a heating chamber 202, a first layer film forming chamber 203, a buffer chamber 204, a second layer film forming chamber 205, and an unload lock chamber 206. According to the film forming device 200, the chambers 201, 202, 203, 204, 205, and 206 are positioned in one line. A gate bulb 207 is provided between adjacent chambers. A substrate is heated in the heating chamber 202. According to the first layer film forming chamber 203, the first layer 54a is formed, and an appropriate oxygen deficiency is added to the first layer 54a. In the buffer chamber 204, a substrate, on which the first layer 54a is formed, is placed. In the second layer film forming chamber 205, the second layer 54b is formed, and an amount of oxygen, greater than an amount of oxygen included in the first layer 54a, is added to the second layer 54b. Further, the substrate is transported to the film forming device 200 through the load lock chamber 201. The substrate is carried out of the film forming device 200 through the unload lock chamber 206.

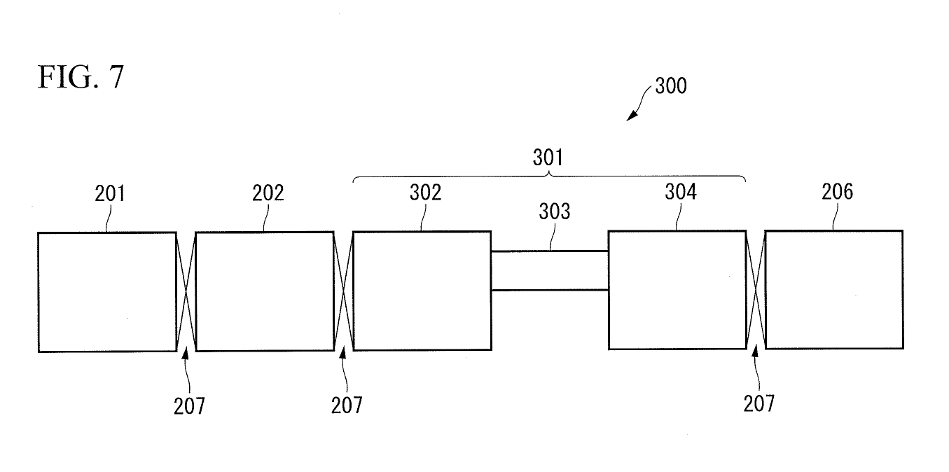

In addition, according to the present embodiment, when an inline type film forming device is used when the first layer 54a and the second layer 54b are formed in series, it is possible to use an inline slit type film forming device 300 as shown in FIG. 7.

The film forming device 300 includes the load lock chamber 201, the heating chamber 202, a film forming chamber 301, and the unload lock chamber 206. According to the film forming device 300, the chambers 201, 202, 203, 301, and 206 are positioned in one line. A gate bulb 207 is provided between adjacent chambers. The film forming chamber 301 includes a first layer film forming region 302, a second layer film forming region 304, and a slit 303. The slit connects the first layer film forming region 302 and the second film forming region 304. A gate bulb is not provided between the first layer film forming region 302 and the second film forming region 304. According to the first layer film forming chamber 302, the first layer 54a is formed, and an appropriate oxygen deficiency is added to the first layer 54a. The substrate, on which the first layer 54a is formed, is transported to the second layer film forming region 304 via a slit 303. In the second layer film forming chamber 304, the second layer 54b is formed, and an amount of oxygen, greater than an amount of oxygen included in the first layer 54a, is added to the second layer 54b. It is possible to form a film in the film forming chamber 301 simultaneously with respect to the first layer film forming region 302 and the second film forming region 304.

An inline type film forming device has been described with reference to FIGS. 6 and 7. However, it is also possible to use a roll-to-roll type film forming device.

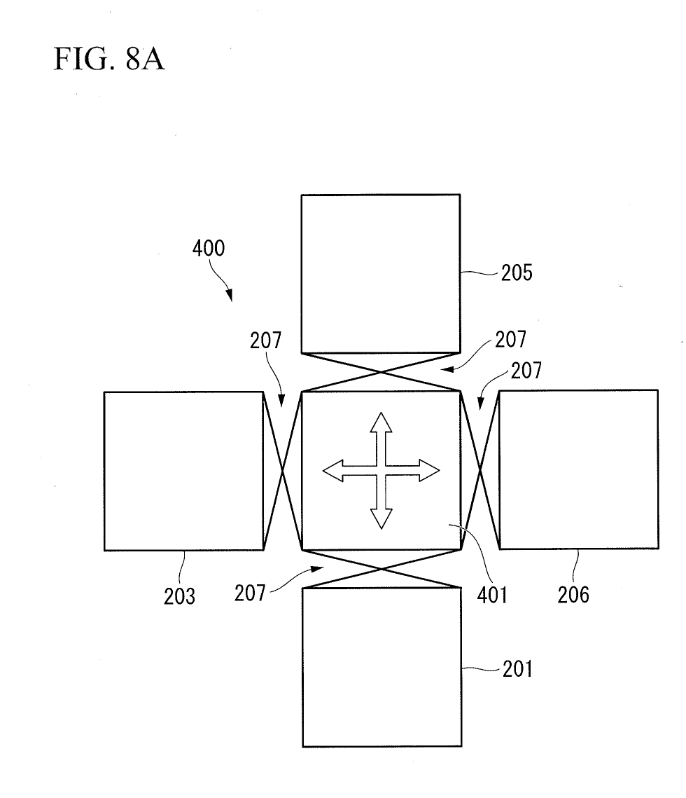

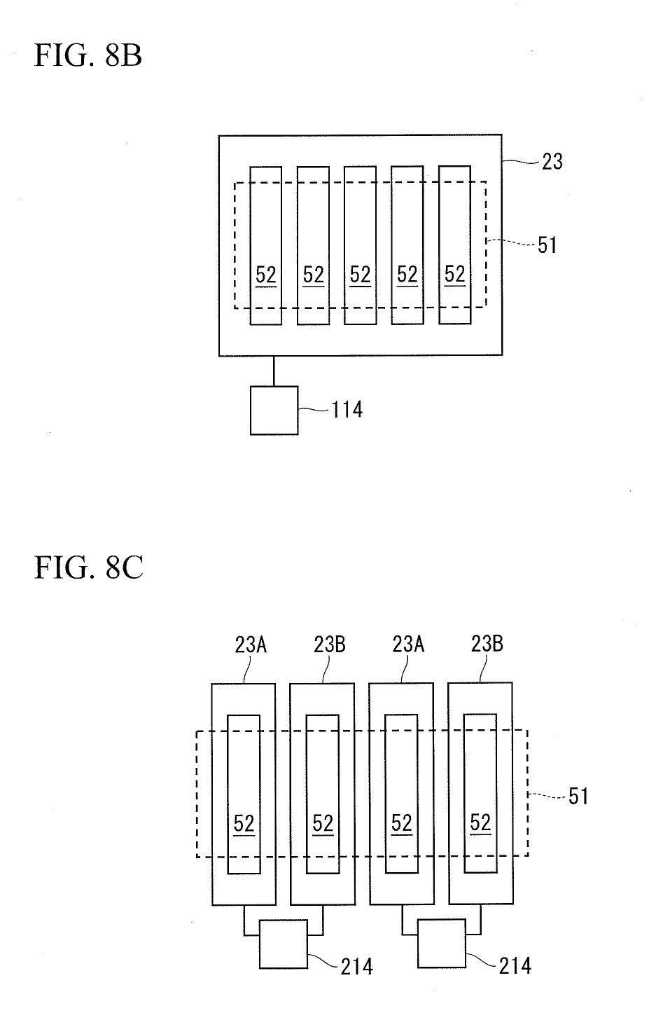

Meanwhile, when a cluster type film forming device is used, it is possible to use a single wafer type film forming device shown in FIG. 8A. The film forming device 400 includes a transfer chamber 401, the load lock chamber 201, the first layer film forming chamber 203, the second layer film forming chamber 205, and the unload lock chamber 206. A gate bulb 207 is provided between each of the transfer chamber 401 and the chambers 201, 203, 205, and 206. The transfer chamber 401 includes a robot arm which transports a substrate. The robot arm transports a substrate from the load lock chamber 201 to the first layer film forming chamber 203. The robot arm also transports a substrate from the first layer film forming chamber 203 to the second layer film forming chamber 205. The robot arm also transports a substrate from the second layer film forming chamber 205 to the unload lock chamber 206.

A cluster type film forming device has been described with reference to FIG. 8A. However, it is also possible to use a carousel type film forming device.

The technical scope of the present invention is not limited by the embodiments described above. Various alterations may be made without deviating from the gist of the present invention. In other words, the specific materials and structures described in the above embodiments are only examples of the present invention. Various modifications may be made as appropriate.

For example, in the embodiment described above, a film forming device was described such that a power source 14 is used to apply a sputtering voltage to a back surface plate 23 on which a target 7 is mounted. The sputtering voltage is obtained by superimposing a high-frequency voltage to the direct current voltage. The present invention is not limited to this film forming device.

For example, as shown in the planar view in FIG. 8B, the present invention may be applied to a film forming device which supplies only a direct current voltage to the back surface plate 23. In FIG. 8B, the direct current power source 114 is used. A plurality of magnets 52 (magnets 26, 27) are placed at a back surface of the back surface plate 23.

Further, the substrate 51 is placed so as to face the target 7 provided on the back surface plate 23.

Further, as shown in the planar view in FIG. 8C, the present invention may be applied to a film forming device which provides only an AC voltage to the back surface plate 23. In FIG. 8C, two AC power sources 214 are used. A back surface plate 23A and a back surface plate 23B are respectively connected to the two AC power sources 214. In addition, a magnet 52 (magnet 26, 27) is placed on each back surface of the back surface plates 23A, 23B. Further, the substrate 51 is placed so as to face the target 7 provided on the back surface plates 23A, 23B.

### WORKING EXAMPLES

Hereinafter, Working Examples according to the present invention are described with respect to the figures.

A transparent conductive film was formed on a substrate using a film forming device (sputtering device) 1 as shown in FIGS. 2 and 3.

### Working Example 1

First, a target 7 of a size 300 mm×610 mm was attached to a sputter cathode mechanism 12. As an ingredient of the target 7, ZnO, which is a primary component, was used. In addition, a material containing 2 mass % of Al₂O₃ was also contained in the ingredient as an impurity. Further, the output of the heater 11 was adjusted so that the temperature of the substrate equals 250° C. In this way, the film forming chamber 3 was heated.

Thereafter, an alkali-free glass substrate (substrate 6) was transported into the transfer chamber 2. The pressure inside the transfer chamber 2 was reduced using a coarse exhaust unit 4. Then, the substrate 6 was transported to the film forming chamber 3. At this time, the pressure inside the film forming chamber is maintained at a predetermined vacuum level by a high vacuum exhaust unit 13.

Next, 270 sccm of Ar gas was provided from the sputter gas introduction unit 15 to the film forming unit 3. The pressure inside the film forming chamber 3 was controlled to be a predetermined sputtering pressure (0.67 Pa) by adjusting a conductance of a conductance bulb. Thereafter, a sputtering was performed on a ZnO series target attached to a sputter cathode mechanism 12, by applying an electric power of 8.4 kW from the DC power source to the sputter cathode mechanism 12.

According to the series of steps described above, a first layer was formed on an alkali-free glass substrate. The thickness of the first layer is 300 nm. The first layer makes up the ZnO series transparent conductive film. Thereafter, 270 sccm of Ar gas and 10 sccm of oxygen gas were supplied to the film forming chamber 3 as a process gas from the sputter gas introduction unit 15. By adjusting the conductance of the conductance bulb, the pressure inside the film forming chamber 3 was controlled again to be equal to a predetermined sputter pressure (0.67 Pa). Thereafter, by performing a sputtering process on a ZnO series target, a second layer was formed on the first layer. The thickness of the second layer is 300 nm. Thereafter, the substrate was removed from the transfer chamber 2. On this substrate, a transparent conductive film including a first layer and a second layer is formed. After forming the transparent conductive film, a wet etching was performed for 180 to 300 seconds using a hydrochloric acid of a 0.01 mass %. Thus, a texture was formed on the front surface of the transparent conductive film.

In particular, according to the Working Example 1, a texture was formed on the front surface of the transparent conductive film by performing a wet etching for 180 seconds.

### Working Example 2

In Working Example 2, a texture was formed on the front surface of the transparent conductive film by performing a wet etching for 240 seconds. According to the Working Example 2, a transparent conductive film was formed including a first layer and a second layer, similar to the Working Example 1.

### Working Example 3

In Working Example 3, a texture was formed on the front surface of the transparent conductive film by performing a wet etching for 300 seconds. According to the Working Example 3, a transparent conductive film was formed including a first layer and a second layer, similar to the Working Example 1.

In other words, according to Working Examples 1-3, the amount of time during which the wet etching is performed is different. The steps for forming the transparent conductive film and the steps for forming the texture are the same.

### Comparative Example 1

In Comparative Example 1, a sputter pressure was set to be a single pressure of 5 mTorr. The amount of oxygen was not increased. A transparent conductive film was formed, which has a predetermined thickness and includes a single layer. The rest of the steps in Comparative Example 1 are the same as those in Working Example 1 above. In addition, a wet etching was performed for a predetermined amount of time using a hydrochloric acid of a 0.01 mass %. Thus, a texture was formed on a front surface of the transparent conductive film.

An SEM image (Scanning Electron Microscope Image) of a transparent conductive film created as described above according to Working Examples 1-3 and the Comparative Example 1 is shown in each of FIGS. 9-12.

Each one of FIGS. 9-11 shows an SEM image for Working Examples 1-3. FIG. 12 shows an SEM image for Comparative Example 1.

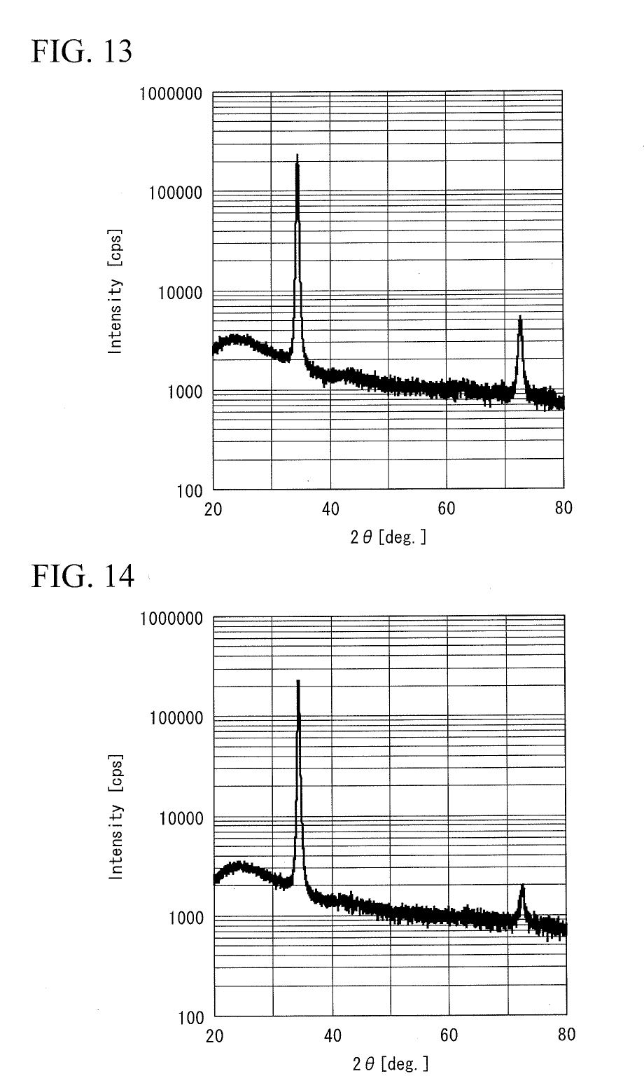

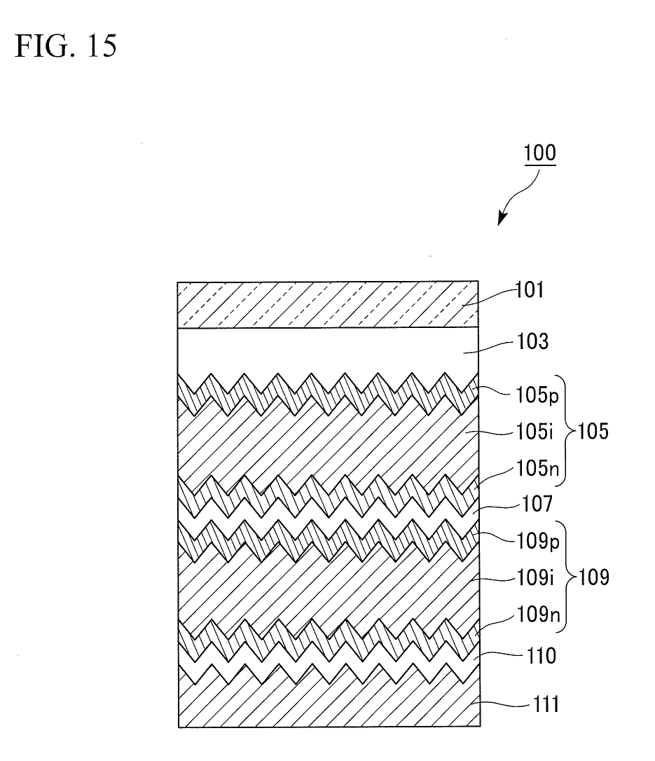

Further, FIG. 13 and FIG. 14 show a measurement result obtained by using an XRD on a transparent conductive film before the etching process was performed in Working Examples 1-3 and Comparative Example 1. The measurement result regarding Working Examples 1-3 is shown in FIG. 13. The measurement result regarding Comparative Example 1 is shown in FIG. 14.

Further, in order to examine the effect brought about by the textured shape in Working Examples 1-3 and Comparative Example 1, an evaluation was performed on the optical characteristics of a single film. In addition, an evaluation was performed on the properties of a solar cell including an upper electrode including a transparent conductive film obtained as described above. In the evaluation of the optical characteristics of the single film, the HAZE METER HM-150 (manufactured by the Murakami Color Research Laboratory Co., Ltd.) was used. In the evaluation of the properties of the solar cell, first, a mini cell solar cell was formed including an upper electrode including a transparent conductive film obtained as described above. Thus, the properties of the solar cell were evaluated using the solar simulator YSS-50A (manufactured by the Yamashita Denso Corporation).

According to the transparent conductive film based on Working Examples 1-3 and Comparative Example 1, the conditions for forming the transparent conductive film, the amount of time during which the etching process was performed, optical characteristics, and the properties of the solar cell are shown in Table 1. As properties of the solar cell, a conversion efficiency (Eff), a short-circuit current density (Jsc), and a fill factor (ft) was evaluated.

TABLE 1

| | | Working | Working | Working | Comparative |
|---|---|---|---|---|---|
| | | Example 1 | Example 2 | Example 3 | Example 1 |
| First Layer | Film Thickness (nm) | 300 | 300 | 300 | 500 |
| | Amount of Oxygen | 0 | 0 | 0 | 0 |
| | Introduced (%) | | | | |
| Second Layer | Film Thickness (nm) | 300 | 300 | 300 | — |
| | Amount of Oxygen | 3.7 | 3.7 | 3.7 | — |
| | Introduced (%) | | | | |
| Optical | Transparency Rate of | 82.8 | 83.1 | 80.9 | 85.7 |
| Characteristics | All Light Beams (%) | | | | |
| | Transparency Rate of | 7.6 | 12.0 | 21.9 | 2.3 |
| | Dispersed Light | | | | |
| | Beams (%) | | | | |
| | Haze Ratio (%) | 9.2 | 14.4 | 27.1 | 2.7 |
| | Transparency Rate of | 75.2 | 71.1 | 59.0 | 83.4 |
| | Parallel Light Beams | | | | |
| | (%) | | | | |
| Properties of Solar | Conversion | 8.95 | 9.24 | 9.51 | 7.48 |
| Cell | Efficiency (%) | | | | |
| | Short-Circuit Current | 14.22 | 14.94 | 15.29 | 13.15 |
| | Density Jsc (mA/cm²) | | | | |
| | Fill Factor F.F. | 0.71 | 0.71 | 0.72 | 0.66 |

As indicated from FIGS. 9-12, the SEM image of Comparative Example 1 shown in FIG. 12 suggests that a minute texture having an adequate size is not formed uniformly. On the other hand, according to the SEM images of Working Examples 1-3 shown in FIGS. 9-11, an appropriate minute texture is formed.

Further, as is evident from the XRD measurement result of the transparent conductive film shown in FIGS. 13 and 14, an orientation of a (004) surface of the transparent conductive film in Working Examples 1-3 is enhanced.

In other words, the characteristics of a minute texture of the transparent conductive film in Working Examples 1-3 shown in the SEM images in FIGS. 9-11 are substantiated by the XRD measurement result described above.

According to the transparent conductive film in Working Examples 1-3, an etching process progresses in a plurality of directions. Thus, a minute texture may be formed. As a result, it is possible to obtain an effect of enhancing the orientation of a (004) surface.

Further, as is evident from Table 1, the short-circuit current density according to Working Examples 1-3 in which a minute texture was formed is higher than the short-circuit current density according to the Comparative Example 1. In other words, according to the Working Examples 1-3, the dispersion effect of light is improved. Further, it is recognized that there is a large amount of electricity produced in the electrical generating layer. Further, as the short-circuit current density improves, the photoelectric conversion efficiency also improves. Therefore, it has been confirmed that a manufacturing method according to the present invention is effective heightening the efficiency of solar cells.

### INDUSTRIAL APPLICABILITY

The present invention may be widely applied to a solar cell and a manufacturing method of a solar cell such that an upper electrode includes a transparent conductive film which includes ZnO as a primary component. The upper electrode serves as an electrode which obtains electric power as light enters.

### DESCRIPTION OF REFERENCE NUMERALS

50 Solar Cell
51 Glass Substrate (Substrate)
53 Upper Electrode
54 Transparent Conductive Film
54a First Layer
54b Second Layer
55 Top Cell
59 Bottom Cell
57 Intermediate Electrode
61 Buffer Layer
63 Back Surface Electrode

1. A manufacturing method of a solar cell comprising a transparent conductive film formed on a transparent substrate, the manufacturing method comprising the steps of:
preparing a target, the target comprising ZnO and a material comprising a substance comprising an Al or a Ga, the ZnO being a primary component of the target;
in a first atmosphere comprising a process gas, applying a sputter electric voltage to the target and forming a first layer comprised in the transparent conductive film;
in a second atmosphere comprising a greater amount of an oxygen gas compared to the first atmosphere, applying a sputter electric voltage to the target and forming a second layer on the first layer, the second layer being comprised in the transparent conductive film; and
forming an irregular shape by performing an etching process on the transparent conductive film.

2. A solar cell comprising:
a transparent substrate;
a transparent conductive film comprising a first layer and a second layer, the transparent film also comprising ZnO as a primary component, the transparent film also comprising an irregular shape, the first layer being placed at a position close to the transparent substrate, the second layer being placed at a position close to an electricity generating layer, the second layer comprising a greater amount of oxygen compared to an amount of oxygen comprised in the first layer;
an electricity generating layer formed on the transparent conductive film; and
a back surface electrode formed on the electricity generating layer.

3. The solar cell according to claim 2, wherein an amount of oxygen comprised in the second layer is larger than the amount of oxygen comprised in the first layer by 0.5-3 mass %.

4. The solar cell according to claim 2, wherein:
the second layer is placed on the first layer so that the second layer is in contact with the first layer; and
a depth of the irregular shape is larger than a thickness of the second layer, and the irregular shape is formed on the second layer.
